(19) United States
(12) Patent Application Publication
(10) Pub. No.: US 2025/0087429 A1
(43) Pub. Date: Mar. 13, 2025

(54) CAPACITOR ARRAY

(71) Applicant: Murata Manufacturing Co., Ltd., Nagaokakyo-shi (JP)

(72) Inventor: Takuya AMAMOTO, Nagaokakyo-shi (JP)

(21) Appl. No.: 18/955,117

(22) Filed: Nov. 21, 2024

Related U.S. Application Data
(63) Continuation of application No. PCT/JP2023/016082, filed on Apr. 24, 2023.

(30) Foreign Application Priority Data
Jun. 9, 2022 (JP) 2022-093677

(51) Int. Cl. H01G 9/26; H01G 9/008; H01G 9/048; H01G 9/07; H01G 9/10

(52) U.S. Cl. CPC H01G 9/26; H01G 9/008; H01G 9/048; H01G 9/07; H01G 9/10

(57) ABSTRACT

A capacitor array that includes: a plurality of capacitor portions arranged in a plane direction or plane directions orthogonal to a thickness direction; and a sealing portion enclosing the plurality of capacitor portions so as to cover opposed main surfaces of the plurality of capacitor portions, the sealing portion including a plurality of sealing layers laminated in the thickness direction, and the plurality of sealing layers including: a first sealing layer proximal to the capacitor portions in the thickness direction, and containing a first insulating material; and second sealing layers on opposite respective sides of the first sealing layer relative to the capacitor portions in the thickness direction and forming two main surfaces of the sealing portion opposed to each other in the thickness direction, and containing a second insulating material.

### CROSS REFERENCE TO RELATED APPLICATIONS

The present application is a continuation of International application No. PCT/JP2023/016082, filed Apr. 24, 2023, which claims priority to Japanese Patent Application No. 2022-093677, filed Jun. 9, 2022, the entire contents of each of which are incorporated herein by reference.

### TECHNICAL FIELD

The present disclosure relates to a capacitor array.

### BACKGROUND ART

Patent Document 1 discloses a capacitor array including: a plurality of solid electrolytic capacitor elements into which one solid electrolytic capacitor sheet is divided; a sheet-shaped first sealing layer; and a sheet-shaped second sealing layer. The solid electrolytic capacitor sheet includes an anode plate composed of a valve metal, a porous layer located on at least one of the main surfaces of the anode plate, a dielectric layer located on the surface of the porous layer, and a cathode layer located on the surface of the dielectric layer and including a solid electrolyte layer. The solid electrolytic capacitor sheet has a first main surface and a second main surface opposed to each other in the thickness direction. Each of the solid electrolytic capacitor elements is located with its first main surface side on the first sealing layer, and the second sealing layer covers the second main surface sides of the plurality of solid electrolytic capacitor elements located on the first sealing layer. The solid electrolytic capacitor elements are separated by sheet removed portions in the form of slits.

Patent Document 1: Japanese Unexamined Patent Application Publication No. 2020-167361

### SUMMARY OF THE DISCLOSURE

The capacitor array described in Patent Document 1 includes the sealing layers placed around and enclosing the plurality of solid electrolytic capacitor elements. However, the capacitor array described in Patent Document 1 has room for improvement in terms of reducing warps, distortions, undulations, and the like resulting from the sealing layers, in other words, reducing degradation in the flatness (coplanarity).

The present disclosure has been made to solve the above issue, and an object thereof is to provide a capacitor array in which degradation in the flatness is reduced.

A capacitor array of the present disclosure includes: a plurality of capacitor portions arranged in a plane direction or plane directions orthogonal to a thickness direction; and a sealing portion enclosing the plurality of capacitor portions so as to cover opposed main surfaces of the plurality of capacitor portions, wherein the sealing portion includes a plurality of sealing layers laminated in the thickness direction, and the plurality of sealing layers include: a first sealing layer proximal to the capacitor portions in the thickness direction, and containing a first insulating material; and second sealing layers on opposite respective sides of the first sealing layer relative to the capacitor portions in the thickness direction and forming two main surfaces of the sealing portion opposed to each other in the thickness direction, and containing a second insulating material.

With the present disclosure, it is possible to provide a capacitor array in which degradation in the flatness is reduced.

### BRIEF DESCRIPTION OF THE DRAWINGS

FIG. 1 is a schematic plan view of an example of a capacitor array according to the present disclosure.

FIG. 2 is a schematic cross-sectional view of an example of a cross section of the capacitor array illustrated in FIG. 1 taken along line segment A1-A2.

FIG. 3 is an enlarged schematic cross-sectional view of the region surrounded by the dashed lines in FIG. 2.

FIG. 4 is a schematic cross-sectional view of an example of a cross section of the capacitor array illustrated in FIG. 1 taken along line segment B1-B2.

FIG. 5 is an enlarged schematic cross-sectional view of the region surrounded by the dashed lines in FIG. 4.

FIG. 6 is an enlarged schematic cross-sectional view of a via conductor and its periphery in a capacitor array for the case the insulating material composing the second sealing layer contains a glass cloth.

### DESCRIPTION OF THE PREFERRED EMBODIMENTS

Hereinafter, a capacitor array of the present disclosure will be described. The present disclosure is not limited to the following configurations, which may be changed as appropriate within a range not departing from the spirit of the present disclosure. Combinations of two or more individual preferred configurations described in the following are also included in the present disclosure.

The drawings described in the following are schematic, and hence, the dimensions, the scale of the ratio of longitudinal dimensions and lateral dimensions, and the like sometimes differ from those of the actual product.

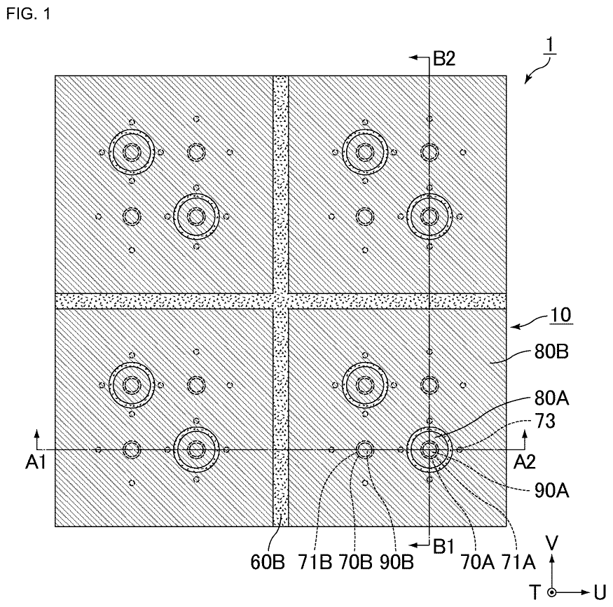

FIG. 1 is a schematic plan view of an example of a capacitor array according to the present disclosure.

The capacitor array 1 illustrated in FIG. 1 includes a plurality of capacitor portions 10.

The number of capacitor portions 10 is two or more and is not limited to specific numbers.

The plurality of capacitor portions 10 are arranged in a flat layout in (a) plane direction(s) orthogonal to the thickness direction T. In the example illustrated in FIG. 1, the plurality of capacitor portions 10 are arranged in a flat layout so as to be aligned in the first direction U orthogonal to the thickness direction T and in the second direction V orthogonal to the thickness direction T and the first direction U. In other words, the plane directions include the first direction U and the second direction V.

The plurality of capacitor portions 10 may be aligned in a plurality of directions as illustrated in FIG. 1, or may be aligned in one direction. The plurality of capacitor portions 10 may be arranged regularly or irregularly.

Examples of the planar shape of the capacitor portion 10 when viewed in the thickness direction T include rectangles (squares or non-square rectangles) as illustrated in FIG. 1; polygons such as quadrilaterals excluding rectangles, triangles, pentagons, and hexagons; circles; and ellipses.

The planar shapes of the plurality of capacitor portions 10 when viewed in the thickness direction T may be the same as one another or may be different from one another, or some of the planar shapes of the capacitor portions 10 may be different.

The areas of the plurality of capacitor portions 10 when viewed in the thickness direction T may be the same as one another or may be different from one another, or some of the areas of the capacitor portions 10 may be different.

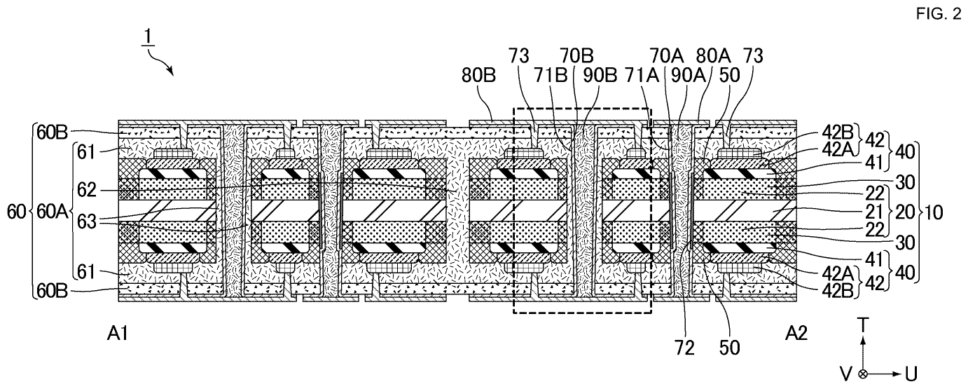

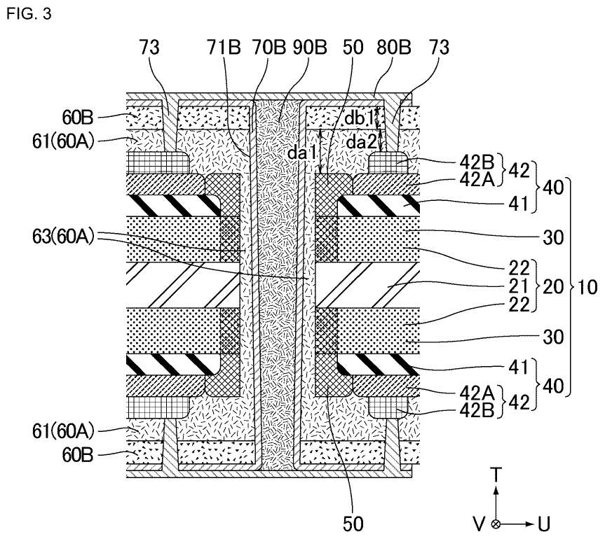

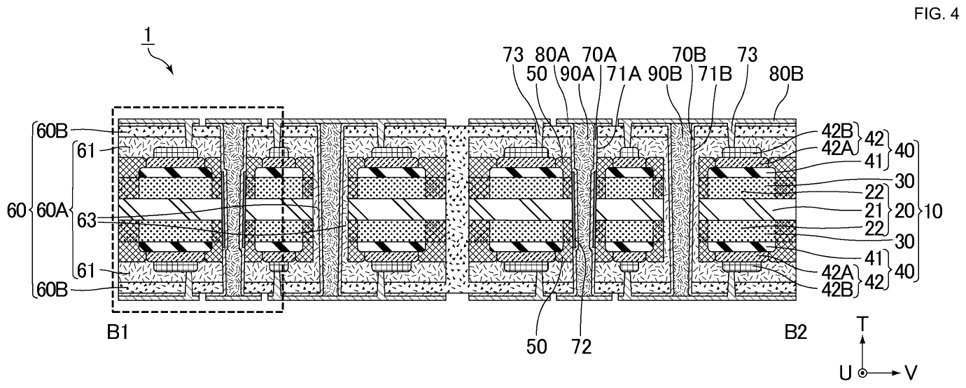

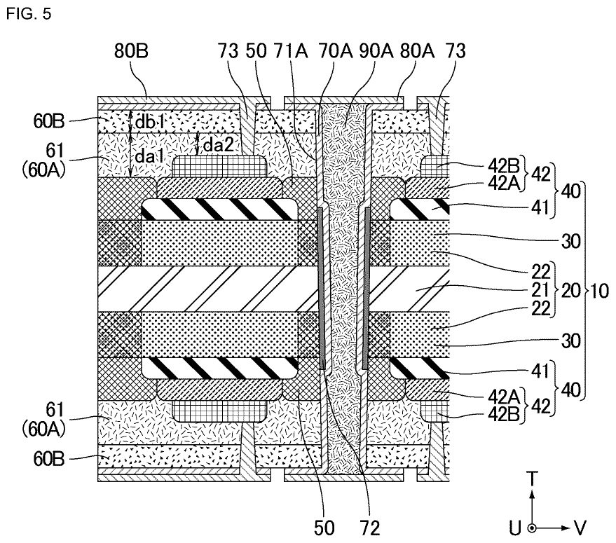

FIG. 2 is a schematic cross-sectional view of an example of a cross section of the capacitor array illustrated in FIG. 1 taken along line segment A1-A2. FIG. 3 is an enlarged schematic cross-sectional view of the region surrounded by the dashed lines in FIG. 2. FIG. 4 is a schematic cross-sectional view of an example of a cross section of the capacitor array illustrated in FIG. 1 taken along line segment B1-B2. FIG. 5 is an enlarged schematic cross-sectional view of the region surrounded by the dashed lines in FIG. 4.

As illustrated FIGS. 2 to 5, the capacitor portion 10 includes an anode plate 20, dielectric layers 30, and cathode layers 40.

The following describes an example of a configuration in which the capacitor portion 10 is configured to be an electrolytic capacitor.

The anode plate 20 includes a core portion 21 and porous layers 22.

It is preferable that the core portion 21 be composed of a metal. In particular, it is preferable that the core portion 21 be composed of a valve metal. In the case in which the core portion 21 is composed of a valve metal, the anode plate 20 is also referred to as a valve metal substrate.

Examples of the valve metal include pure metals such as aluminum, tantalum, niobium, titanium, and zirconium and alloys containing at least one of these pure metals. Among these, aluminum or aluminum alloys are preferable.

The porous layer 22 is located on at least one main surface of the two main surfaces of the core portion 21 opposed to each other in the thickness direction T. In other words, the porous layer 22 may be located on only one main surface of the core portion 21 or may be located on both main surfaces of the core portion 21 as illustrated in FIG. 2. As described above, the anode plate 20 includes a porous layer 22 on at least one main surface of the two main surfaces opposed to each other in the thickness direction T. This enables the surface area of the anode plate 20 to be large, making it easy to improve the capacitance of the capacitor portion 10.

It is preferable that the porous layer 22 be an etching layer formed by etching a surface of the anode plate 20.

It is preferable that the anode plate 20 have a flat plate shape, and it is more preferable that the anode plate 20 have a foil shape.

In the present specification, plate shapes include foil shapes, sheet shapes, and film shapes, and these are not discriminated according to the dimensions in the thickness direction.

The dielectric layer 30 is located on the surface of the porous layer 22. More specifically, the dielectric layer 30 is located along the surface (outline) of pores in the porous layer 22.

It is preferable that the dielectric layer 30 be composed of an oxide film of a valve metal mentioned above. For example, in the case in which the anode plate 20 is composed of an aluminum foil, an oxide film serving as the dielectric layer 30 is formed by performing anodic oxidation (which is also referred to as a chemical conversion treatment) on the anode plate 20 in a water solution containing ammonium adipate or the like. Since the dielectric layer 30 is formed along the surface of the porous layer 22, the dielectric layer 30 has pores (recesses).

The cathode layer 40 is located on the surface of the dielectric layer 30.

It is preferable that the cathode layer 40 include a solid electrolyte layer 41 located on the surface of the dielectric layer 30 and a conductor layer 42 located on the surface of the solid electrolyte layer 41. In the case in which the cathode layer 40 includes the solid electrolyte layer 41, the capacitor portion 10 is configured to be a solid electrolytic capacitor.

It is preferable that the solid electrolyte layer 41 include an inner layer located inside the pores of the dielectric layer 30 and an outer layer covering the inner layer.

Examples of the constituent material of the solid electrolyte layer 41 include conductive polymers such as polypyrroles, polythiophenes, and polyanilines. Among these, polythiophenes are preferable, and in particular, poly(3,4-ethylenedioxythiophene) (PEDOT) is preferable. The conductive polymer may contain a dopant such as polystyrene sulfonic acid (PSS).

The solid electrolyte layer 41 is formed in a specified region on the surface of the dielectric layer 30, for example, by a method including applying a dispersion of a conductive polymer such as poly(3,4-ethylenedioxythiophene) onto the surface of the dielectric layer 30 and drying it, a method including forming a film of a polymer such as poly(3,4-ethylenedioxythiophene) on the surface of the dielectric layer 30 by using a treatment liquid containing a polymerizable monomer such as 3,4-ethylenedioxythiophene, or other methods.

The conductor layer 42 preferably includes a conductive resin layer 42A located on the surface of the solid electrolyte layer 41 and a metal layer 42B located on the surface of the conductive resin layer 42A.

Examples of the conductive resin layer 42A include a conductive adhesive layer containing at least one kind of conductive fillers selected from the group of copper fillers, silver fillers, nickel fillers, and carbon fillers.

It is preferable that the metal layer 42B contain metal fillers.

It is preferable that the metal fillers be at least one kind of fillers selected from the group of copper fillers, silver fillers, and nickel fillers.

The metal layer 42B may be, for example, a metal plating film, a metal foil, or the like. In this case, it is preferable that the metal layer 42B be composed of at least one kind of metal selected from the group of copper, silver, nickel, and alloys containing at least one of these metals as the main component.

In the present specification, the main component denotes the element component having the largest weight ratio.

The conductor layer 42 may include, for example, a carbon layer as the conductive resin layer 42A and a copper layer as the metal layer 42B.

The carbon layer is formed in a specified region, for example, by applying a carbon paste containing carbon fillers onto the surface of the solid electrolyte layer 41 by a sponge transfer method, a screen printing method, a dispenser application method, an inkjet printing method, or the like.

The copper layer is formed in a specified region, for example, by applying a copper paste containing copper fillers onto the surface of the carbon layer by a sponge transfer method, a screen printing method, a spray application method, a dispenser application method, an inkjet printing method, or the like.

The conductor layer 42 may include at least one of the conductive resin layer 42A and the metal layer 42B. Specifically, the conductor layer 42 may include only the conductive resin layer 42A, may include only the metal layer 42B, or may include both the conductive resin layer 42A and the metal layer 42B as illustrated in FIG. 2 and other figures.

The capacitor portion 10 preferably further includes a mask layer 50 located at peripheral edges of the porous layers 22 when viewed in the thickness direction T. This configuration provides the insulation between the anode plate 20 and the cathode layer 40, preventing a short circuit between them.

The mask layer 50 is preferably provided at the entire peripheral edges of the porous layer 22. However, the mask layer 50 may be provided at part of the peripheral edges of the porous layer 22.

It is preferable that the mask layer 50 extend inward in the thickness direction T from at least one main surface of the two main surfaces of the anode plate 20, and it is more preferable that the mask layer 50 extend inward from both main surfaces of the anode plate 20.

The mask layer 50 may be in contact with the core portion 21 in the thickness direction T but does not have to be in contact with the core portion 21 in the thickness direction T.

The mask layer 50 may be located not only inside the porous layer 22 but also outside the porous layer 22. In this case, the mask layer 50 may be infiltrated into the porous layer 22 and also located on the surface of the porous layer 22 where the mask layer 50 is infiltrated. In other words, the dimension of the mask layer 50 in the thickness direction T may be larger than the dimension of the porous layer 22 in the thickness direction T.

In the case in which the mask layer 50 is also located outside the porous layer 22, it is preferable that the mask layer 50 be located in a region surrounding the cathode layer 40 when viewed in the thickness direction T.

When viewed in the thickness direction T, the mask layer 50 may partially overlap the cathode layer 40, but a configuration in which the mask layer 50 does not overlap the cathode layer 40 at all is also possible.

The mask layer 50 is composed of an insulating material.

Examples of the insulating material composing the mask layer 50 include polyphenylsulfone (PPS), polyethersulfone (PES), cyanate ester resins, fluororesins (tetrafluoroethylene, tetrafluoroethylene-perfluoroalkylvinyl ether copolymer, and the like), compositions including a soluble polyimide siloxane and an epoxy resin, polyimide resins, polyamideimide resins, derivatives or precursors of one of these.

The mask layer 50 is formed in the peripheral edges of the porous layer 22, for example, by applying a foregoing insulating material onto the portions of both main surfaces of the anode plate 20, overlapping the peripheral edges of the porous layer 22, and infiltrating the applied material into the two main surfaces of the anode plate 20.

The mask layer 50 may be formed in the porous layer 22 before the dielectric layer 30 is formed or after the dielectric layer 30 is formed.

The capacitor array 1 illustrated in FIGS. 2 and 4 further includes a sealing portion 60, in addition to the plurality of capacitor portions 10.

The sealing portion 60 encloses the plurality of capacitor portions 10 so as to cover both main surfaces of the plurality of capacitor portions 10 opposed to each other in the thickness direction T. This enables the plurality of capacitor portions 10 to be protected by the sealing portion 60.

The sealing portion 60 is composed of insulating materials. In other words, the sealing portion 60 functions as an insulation portion.

The sealing portion 60 includes a plurality of sealing layers laminated in the thickness direction T.

The plurality of sealing layers in the sealing portion 60 include a first sealing layer 60A and second sealing layers 60B. In the example illustrated in FIG. 2 and other figures, the sealing portion 60 includes the first sealing layer 60A and the second sealing layers 60B laminated in order from the capacitor portions 10 in the thickness direction T. In other words, in the example illustrated in FIG. 2 and other figures, the second sealing layers 60B adjoin the opposite sides of the first sealing layer 60A from the capacitor portions 10.

The first sealing layer 60A of the plurality of sealing layers is located closest to the capacitor portions 10 in the thickness direction T. Hence, the first sealing layer 60A functions as a sealing layer conforming to the surface shapes of the capacitor portions 10.

The second sealing layers 60B are located on the opposite sides of the first sealing layer 60A from the capacitor portions 10 in the thickness direction T and serve as two main surfaces of the sealing portion 60 opposed to each other in the thickness direction T. In other words, the second sealing layers 60B are located at the outermost surfaces of the sealing portion 60. Hence, the second sealing layers 60B function as sealing layers that flatten both main surfaces of the sealing portion 60, in other words, both main surfaces of the capacitor array 1.

In the sealing portion 60 of the capacitor array 1, mainly the first sealing layer 60A can play a role of enclosing the capacitor portions 10, and mainly the second sealing layers 60B can play a role of flattening both main surfaces of the capacitor array 1, in other words, both main surfaces of the sealing portion 60. Hence, in the capacitor array 1 including the sealing portion 60 composed of a plurality of sealing layers including the first sealing layer 60A and the second sealing layers 60B, warps, distortions, undulations, and the like resulting from the sealing portion 60 are less likely to occur, compared with those in the case of a capacitor array including a sealing portion having only one sealing layer.

As described above, since the occurrence of warps, distortions, undulations, and the like can be reduced in the capacitor array 1, degradation of the flatness can be reduced.

The sealing portion 60 has only to include at least the first sealing layer 60A and the second sealing layers 60B, but the sealing portion 60 may have at least one sealing layer between the first sealing layer 60A and the second sealing layers 60B.

The insulating material composing the first sealing layer 60A may contain an insulating resin.

Examples of the insulating resin contained in the insulating material composing the first sealing layer 60A include epoxy resins, phenol resins, and polyimide resins.

The insulating material composing the first sealing layer 60A may further contain inorganic fillers.

Examples of the inorganic fillers contained in the insulating material composing the first sealing layer 60A include silica fillers and alumina fillers.

It is preferable that the median diameter D₅₀ of the inorganic fillers contained in the insulating material composing the first sealing layer 60A be 10 μm or less. This range makes it more likely for the first sealing layer 60A to conform to the surface shapes of the capacitor portions 10 even if the first sealing layer 60A contains inorganic fillers.

It is preferable that the median diameter D₅₀ of the inorganic fillers contained in the insulating material composing the first sealing layer 60A be 0.1 μm or more.

The median diameter D₅₀ of the inorganic fillers contained in the insulating material composing the sealing layers is determined as follows: First, a capacitor array is subjected to cutting, polishing, or the like to expose a section in the thickness direction including a target sealing layer, in this case, a section in the thickness direction exposing the first sealing layer as illustrated in FIG. 2. Next, an image of the section is captured by using a scanning electron microscope (SEM) or the like. Then, in the captured sectional image, the region where the first sealing layer is located, and the regions where inorganic fillers inside the first sealing layer are located are checked by using an analysis method such as an energy dispersive X-ray analysis (EDX). Then, an image analysis is performed on the sectional image to measure the equivalent circle diameters of the inorganic fillers in the first sealing layer, and the obtained equivalent circle diameters are considered to be the particle sizes of the inorganic fillers. After that, from the obtained particle sizes of the inorganic fillers, the cumulative particle size distribution by number is determined, and the particle size with a cumulative probability 50% in the cumulative particle size distribution by number is determined as the median diameter D₅₀ of the inorganic fillers.

The first sealing layer 60A is formed to enclose the capacitor portions 10 so as to cover both main surfaces of the capacitor portions 10, for example, by a method including thermal pressure bonding of insulating resin sheets, a method including applying an insulating resin paste and then heat-curing it, or other methods.

The insulating material composing the second sealing layer 60B may contain an insulating resin.

Examples of the insulating resin contained in the insulating material composing the second sealing layer 60B include epoxy resins, phenol resins, and polyimide resins.

It is preferable that the insulating materials composing the first sealing layer 60A and the second sealing layer 60B contain different insulating resins.

In the present specification, “the insulating materials composing a plurality of sealing layers have different insulating resins” denotes that at least the kind of insulating resin is different in the insulating material composing each of the sealing layers, and denotes that the ratio of the insulating resin content to the total amount of insulating material should preferably be different in each sealing layer, in addition to the difference in the kind of insulating resin.

In the case in which the insulating materials composing the first sealing layer 60A and the second sealing layer 60B contain different insulating resins, the first sealing layer 60A and the second sealing layer 60B are likely to have different characteristics.

As described above, in the sealing portion 60 of the capacitor array 1, mainly the first sealing layer 60A plays a role of enclosing the capacitor portions 10, and mainly the second sealing layers 60B play a role of flattening both main surfaces of the sealing portion 60, in other words, both main surfaces of the capacitor array 1. Hence, it is preferable that the first sealing layer 60A and the second sealing layer 60B have different characteristics.

However, the insulating materials composing the first sealing layer 60A and the second sealing layer 60B may contain the same insulating resin.

In the present specification, “the insulating materials composing a plurality of sealing layers contain the same insulating resin” denotes that at least the kind of insulating resin is the same in the insulating material composing each of the sealing layers, and denotes that the ratio of the insulating resin content to the total amount of insulating material should preferably be the same in each sealing layer, in addition to the same kind of insulating resin.

The insulating material composing the second sealing layer 60B may further contain inorganic fillers.

Examples of the inorganic fillers contained in the insulating material composing the second sealing layer 60B include silica fillers and alumina fillers.

The inorganic fillers contained in the insulating materials composing the first sealing layer 60A and the second sealing layer 60B may be the same or may be different in terms of at least their kinds.

The median diameters D₅₀ of the inorganic fillers contained in the insulating materials composing the first sealing layer 60A and the second sealing layer 60B may be the same or may be different.

The ratio of the inorganic filler content to the total amount of the insulating material in each of the first sealing layer 60A and the second sealing layer 60B may be the same or different.

The insulating material composing the second sealing layer 60B may further contain a glass cloth. In this case, the rigidity of the second sealing layer 60B is likely to be high, and this makes it easy to maintain the flatness of the second sealing layer 60B. In other words, it is easy to maintain the flatness of the capacitor array 1.

Examples of insulating materials containing a glass cloth include prepreg.

After the first sealing layer 60A is formed by an aforementioned method, the second sealing layers 60B are formed to adjoin the opposite sides of the first sealing layer 60A from the capacitor portions 10, for example, by a method including thermal pressure bonding of insulating resin sheets, a method including applying an insulating resin paste and then heat-curing it, or other methods. In the case in which the second sealing layers 60B are formed on the first sealing layer 60A by a build-up method as mentioned above, the already formed first sealing layer 60A need not be soften by a heat treatment when the second sealing layers 60B are formed. Hence, when the second sealing layers 60B are formed, the first sealing layer 60A and the second sealing layers 60B are not integrated, and interfaces are present between the first sealing layer 60A and the second sealing layers 60B.

From the viewpoint of achieving the state in which interfaces are present between the first sealing layer 60A the second sealing layers 60B, it is preferable that the glass transition temperature of the insulating material composing the second sealing layer 60B be lower than the glass transition temperature of the insulating material composing the first sealing layer 60A.

However, the glass transition temperature of the insulating material composing the second sealing layer 60B may be the same as or higher than the glass transition temperature of the insulating material composing the first sealing layer 60A. In the case in which the glass transition temperature of the insulating material composing the second sealing layer 60B is higher than the glass transition temperature of the insulating material composing the first sealing layer 60A, it is easier to maintain the flatness of both main surfaces of the sealing portion 60 that the second sealing layers 60B serve as, in other words, both main surfaces of the capacitor array 1, even if the capacitor array 1 is subjected to a heat treatment in the manufacturing process or the like of the capacitor array 1, compared with the case in which the glass transition temperature of the insulating material composing the second sealing layer 60B is lower than or equal to the glass transition temperature of the insulating material composing the first sealing layer 60A.

The glass transition temperatures of the insulating materials composing the sealing layers are measured by thermogravimeter-differential thermal analysis (TG-DTA) or differential scanning calorimetry (DSC).

It is preferable that the coefficient of linear expansion of the second sealing layer 60B in the thickness direction T be lower than the coefficient of linear expansion of the first sealing layer 60A in the thickness direction T. In the case in which the coefficient of linear expansion of the second sealing layer 60B in the thickness direction T is lower than the coefficient of linear expansion of the first sealing layer 60A in the thickness direction T, it is easier to maintain the flatness of both main surfaces of the sealing portion 60 that the second sealing layers 60B serve as, in other words, both main surfaces of the capacitor array 1, even if the capacitor array 1 is subjected to a heat treatment in the manufacturing process or the like of the capacitor array 1, compared with the case in which the coefficient of linear expansion of the second sealing layer 60B in the thickness direction T is higher than or equal to the coefficient of linear expansion of the first sealing layer 60A in the thickness direction T.

However, the coefficient of linear expansion of the second sealing layer 60B in the thickness direction T may be the same as or higher than the coefficient of linear expansion of the first sealing layer 60A in the thickness direction T.

The coefficients of linear expansion of the sealing layers in the thickness direction are measured by thermomechanical analysis (TMA).

The first sealing layer 60A preferably includes first insulation portions 61 each covering one of the two main surfaces of the plurality of capacitor portions 10. In the example illustrated in FIG. 2 and other figures, each first insulation portion 61 covers the cathode layers 40 and the mask layers 50 serving as one of the two main surfaces of the plurality of capacitor portions 10.

The first insulation portions 61 overlap the plurality of capacitor portions 10 when viewed in the thickness direction T.

In the region of the sealing portion 60 on one main surface side of the two main surfaces, it is preferable that the maximum dimension dal of the first insulation portion 61 of the first sealing layer 60A in the thickness direction T and the maximum dimension db1 of the second sealing layer 60B in the thickness direction T be different from each other.

In the region of the sealing portion 60 on one main surface side of the two main surfaces, it is preferable that the maximum dimension dal of the first insulation portion 61 of the first sealing layer 60A in the thickness direction T be larger than the maximum dimension db1 of the second sealing layer 60B in the thickness direction T. This makes it easy for the first insulation portion 61 to conform to the surface shapes of the capacitor portions 10 and to flatten the main surface of the first insulation portion 61 opposite to the capacitor portions 10. Hence, it is easy to flatten both main surfaces of the sealing portion 60, in other words, both main surfaces of the capacitor array 1.

In the region of the sealing portion 60 on one main surface side of the two main surfaces, it is preferable that the ratio (da1/db1) of the maximum dimension dal of the first insulation portion 61 of the first sealing layer 60A in the thickness direction T to the maximum dimension db1 of the second sealing layer 60B in the thickness direction T be 110% or more.

In the region of the sealing portion 60 on one main surface side of the two main surfaces, it is preferable that the ratio (da1/db1) of the maximum dimension dal of the first insulation portion 61 of the first sealing layer 60A in the thickness direction T to the maximum dimension db1 of the second sealing layer 60B in the thickness direction T be 500% or less.

In the region of the sealing portion 60 on one main surface side of the two main surfaces, it is preferable that the maximum dimension dal of the first insulation portion 61 of the first sealing layer 60A in the thickness direction T be 5 μm or more.

In the region of the sealing portion 60 on one main surface side of the two main surfaces, it is preferable that the maximum dimension da1 of the first insulation portion 61 of the first sealing layer 60A in the thickness direction T be 100 μm or less.

In the region of the sealing portion 60 on one main surface side of the two main surfaces, it is preferable that the maximum dimension db1 of the second sealing layer 60B in the thickness direction T be 100 μm or less.

In the region of the sealing portion 60 on one main surface side of the two main surfaces, it is preferable that the maximum dimension db1 of the second sealing layer 60B in the thickness direction T be 5 μm or more.

In the region of the sealing portion 60 on one main surface side of the two main surfaces, the ratio (da2/da1) of the minimum dimension da2 of the first insulation portion 61 of the first sealing layer 60A in the thickness direction T to the maximum dimension dal of the first insulation portion 61 of the first sealing layer 60A in the thickness direction T may be 50% or less. In this case, it can be said that there is a large step on the main surface of the capacitor portion 10 on one main surface side of the sealing portion 60. However, even if there is a large step on one main surface of the capacitor portion 10 in the capacitor array 1, the plurality of sealing layers including the first sealing layer 60A and the second sealing layers 60B enable reduction in degradation in the flatness of the capacitor array 1.

In the region of the sealing portion 60 on one main surface side of the two main surfaces, the ratio (da2/da1) of the minimum dimension da2 of the first insulation portion 61 of the first sealing layer 60A in the thickness direction T to the maximum dimension dal of the first insulation portion 61 of the first sealing layer 60A in the thickness direction T may be 5% or more.

The maximum dimension da1 of the first insulation portion 61 of the first sealing layer 60A in the thickness direction T corresponds to the maximum dimension in the thickness direction T of the portions of the first sealing layer 60A overlapping the plurality of capacitor portions 10 when viewed in the thickness direction T. In the example illustrated in FIGS. 3 and 5, the maximum dimension da1 of the first insulation portion 61 of the first sealing layer 60A in the thickness direction T corresponds to the distance in the thickness direction T between the main surface of the first insulation portion 61 opposite to the capacitor portion 10 and the main surface of the mask layer 50 opposite to the anode plate 20.

The minimum dimension da2 of the first insulation portion 61 of the first sealing layer 60A in the thickness direction T corresponds to the minimum dimension in the thickness direction T of the portions of the first sealing layer 60A overlapping the plurality of capacitor portions 10 when viewed in the thickness direction T. In the example illustrated in FIGS. 3 and 5, the minimum dimension da2 of the first insulation portion 61 of the first sealing layer 60A in the thickness direction T corresponds to the distance in the thickness direction T between the main surface of the first insulation portion 61 opposite to the capacitor portion 10 and the main surface of the cathode layer 40 opposite to the anode plate 20, in this case, the main surface of the conductor layer 42 opposite to the anode plate 20.

The maximum dimension db1 of the second sealing layer 60B in the thickness direction T corresponds to the maximum distance in the thickness direction T between the main surface of the second sealing layer 60B opposite to the capacitor portion 10 and the main surface of the second sealing layer 60B on the capacitor portion 10 side.

The maximum dimension and the minimum dimension of the sealing layers in the thickness direction can be determined as follows: First, a capacitor array is subjected to cutting, polishing, or the like to expose a section in the thickness direction including a target sealing layer, in this case, a section in the thickness direction exposing the first sealing layer and the second sealing layers as illustrated in FIG. 2. Next, an image of the section is captured by using a scanning electron microscope or the like. Then, in the captured sectional image, the region where the first insulation portion of the first sealing layer is located and the region where the second sealing layer is located are checked by using an analysis method such as an energy dispersive X-ray analysis. Then, an image analysis is performed on the sectional image to measure the maximum dimension of the first insulation portion of the first sealing layer in the thickness direction, the minimum dimension of the first insulation portion of the first sealing layer in the thickness direction, and the maximum dimension of the second sealing layer in the thickness direction.

Although the above description is based on a configuration concerning the maximum dimension of the first insulation portion 61 of the first sealing layer 60A in the thickness direction T, the minimum dimension of the first insulation portion 61 of the first sealing layer 60A in the thickness direction T, and the maximum dimension of the second sealing layer 60B in the thickness direction T in the region of the sealing portion 60 on one main surface side of the two main surfaces, the same configuration is preferable in the region of the sealing portion 60 on the other main surface side of the two main surfaces.

The first sealing layer 60A preferably further includes a second insulation portion 62 separating each of the capacitor portions 10 from the others. In the example illustrated in FIG. 2, the second insulation portion 62 is a filling between the two capacitor portions 10 separating one of the two capacitor portions 10 from the other.

The first sealing layer 60A preferably further includes third insulation portions 63 each passing through one of the capacitor portions 10 in the thickness direction T. In the example illustrated in FIG. 2 and other figures, the third insulation portions 63 each pass through the anode plate 20 and the mask layers 50 of one of the capacitor portions 10 in the thickness direction T.

In the case in which the first sealing layer 60A includes the first insulation portions 61, the second insulation portion 62, and the third insulation portions 63, the first insulation portions 61, the second insulation portion 62, and the third insulation portions 63 conform to the surface shapes of the capacitor portions 10.

In the case in which the first sealing layer 60A includes the first insulation portions 61, the second insulation portion 62, and the third insulation portions 63, the first insulation portions 61, the second insulation portion 62, and the third insulation portions 63 may be integrated, so that the interfaces between the insulation portions do not have to be present as illustrated in FIG. 2 and other figures. However, a configuration in which the first insulation portions 61, the second insulation portion 62, and the third insulation portions 63 are not integrated, and the interfaces between the insulation portions are present is possible.

The capacitor array 1 preferably further includes through-hole conductors 70A.

The through-hole conductors 70A pass through the capacitor portions 10 and the sealing portion 60 in the thickness direction T. In the example illustrated in FIG. 2 and other figures, the through-hole conductors 70A pass through not only the capacitor portions 10 but also the first insulation portions 61 of the first sealing layer 60A and the second sealing layers 60B in the thickness direction T.

The through-hole conductor 70A is preferably located at least on the inner wall surface of a through hole 71A extending through the capacitor portion 10 and the sealing portion 60 in the thickness direction T. In the example illustrated in FIG. 2 and other figures, the through-hole conductor 70A is located not throughout the entire inside of the through hole 71A but on the inner wall surface of the through hole 71A.

The through-hole conductor 70A is preferably electrically connected to the anode plate 20 at the inner wall surface of the through hole 71A. More specifically, the through-hole conductor 70A is preferably electrically connected to the end surface of the anode plate 20 facing the inner wall surface of the through hole 71A in the plane directions. Thus, the anode plate 20 is electrically extended to the outside through the through-hole conductor 70A.

It is preferable that the core portion 21 and the porous layers 22 be exposed on the end surface of the anode plate 20 electrically connected to the through-hole conductor 70A. In this case, not only the core portion 21 but also the porous layers 22 are electrically connected to the through-hole conductor 70A.

It is preferable that the through-hole conductor 70A be electrically connected to the anode plate 20 over the entire circumference of the through hole 71A when viewed in the thickness direction T. In this case, the connection resistance between the anode plate 20 and the through-hole conductor 70A is more likely to be low, so that the equivalent series resistance (ESR) of the capacitor portion 10 is more likely to be low.

The through-hole conductor 70A is formed, for example, as follows: First, the through hole 71A is formed so as to extend through the capacitor portion 10 and the sealing portion 60 in the thickness direction T by drilling, laser processing, or the like. The inner wall surface of the through hole 71A is metallized with a metal material containing a low resistance metal such as copper, gold, and silver to form the through-hole conductor 70A. When forming the through-hole conductor 70A, for example, metallizing the inner wall surface of the through hole 71A by electroless copper plating, electrolytic copper plating, or the like makes the processing easy. Instead of the method in which the inner wall surface of the through hole 71A is metallized, the method of forming the through-hole conductor 70A may also be a method in which the through hole 71A is filled with a metal material, a composite material containing a metal and a resin, or the like.

The capacitor array 1 preferably further includes anode connection layers 72 each located between the corresponding anode plate 20 and through-hole conductor 70A in the plane directions. In the example illustrated in FIG. 2 and other figures, the anode connection layer 72 is in contact with both the anode plate 20 and the through-hole conductor 70A.

Since the anode connection layer 72 is located between the anode plate 20 and the through-hole conductor 70A in the plane directions, the anode connection layer 72 functions as a barrier layer for the anode plate 20, more specifically, a barrier layer for the core portion 21 and the porous layers 22. In the case in which the anode connection layer 72 functions as a barrier layer for the anode plate 20, dissolution of the anode plate 20 that occurs during a chemical treatment to form an outer electrode layer 80A described later and the like is reduced, in other words, infiltration of chemicals into the capacitor portion 10 is reduced, which makes it easier to improve the reliability of the capacitor array 1.

The anode plate 20 and the through-hole conductor 70A are preferably electrically connected to each other with the anode connection layer 72 interposed therebetween.

The dimension of the anode connection layer 72 in the thickness direction T is preferably larger than the dimension of the anode plate 20 in the thickness direction T. In this case, since the entire end surface of the anode plate 20 is covered with the anode connection layer 72, the barrier property of the anode connection layer 72 for the anode plate 20 is more likely to be high.

It is preferable that the dimension of the anode connection layer 72 in the thickness direction T be larger than 100% and smaller than or equal to 200% of the dimension of the anode plate 20 in the thickness direction T.

However, the dimension of the anode connection layer 72 in the thickness direction T may be the same as or smaller than the dimension of the anode plate 20 in the thickness direction T.

It is preferable that the through-hole conductor 70A be connected to the anode connection layer 72 over the entire circumference of the through hole 71A when viewed in the thickness direction T. In this case, the contact area between the through-hole conductor 70A and the anode connection layer 72 is large, and thus the connection resistance between the through-hole conductor 70A and the anode connection layer 72 is more likely to be low. Hence, the connection resistance between the anode plate 20 and the through-hole conductor 70A is more likely to be low, and thus the equivalent series resistance of the capacitor portion 10 is more likely to be low. In addition, because the adhesion between the through-hole conductor 70A and the anode connection layer 72 is more likely to be high, defects such as separation between the through-hole conductor 70A and the anode connection layer 72 due to thermal stress are less likely to occur.

It is preferable that the anode connection layer 72 include a layer containing nickel as the main component. In this case, damage to the metal and the like composing the anode plate 20 (for example, aluminum) is low, and this makes it easy to improve the barrier property of the anode connection layer 72 for the anode plate 20.

However, a configuration without the anode connection layer 72 between the anode plate 20 and the through-hole conductor 70A in the plane directions is also possible. In this case, the through-hole conductor 70A may be directly connected to the end surface of the anode plate 20.

The capacitor array 1 preferably includes the outer electrode layers 80A electrically connected to the through-hole conductors 70A. In the example illustrated in FIG. 2 and other figures, the outer electrode layers 80A are located on the surfaces of the through-hole conductors 70A and function as connection terminals of the capacitor array 1 (the capacitor portions 10). In the example illustrated in FIG. 2 and other figures, the outer electrode layers 80A are electrically connected to the anode plate 20 with the through-hole conductor 70A interposed therebetween and function as connection terminals for the anode plate 20.

Examples of the constituent material of the outer electrode layer 80A include a metal material containing a low resistance metal such as silver, gold, and copper. In this case, the outer electrode layer 80A is formed, for example, by plating the surface of the through-hole conductor 70A.

To improve the adhesion between the outer electrode layer 80A and another member, in this case, the adhesion between the outer electrode layer 80A and the through-hole conductor 70A, the constituent material of the outer electrode layer 80A may contain mixed materials of a resin and at least one kind of conductive fillers selected from the group of silver fillers, copper fillers, nickel fillers, and carbon fillers.

The capacitor array 1 preferably further includes resin-filled portions 90A formed by filling the through holes 71A with a resin material. In the example illustrated in FIG. 2 and other figures, the resin-filled portion 90A is located in the space surrounded by the through-hole conductor 70A on the inner wall surface of the through hole 71A. Since the presence of the resin-filled portion 90A eliminates the space in the through hole 71A, it reduces the occurrence of delamination of the through-hole conductor 70A.

It is preferable that the coefficient of thermal expansion of the resin-filled portion 90A be higher than the coefficient of thermal expansion of the through-hole conductor 70A. More specifically, it is preferable that the coefficient of thermal expansion of the resin material placed in the through hole 71A be higher than the coefficient of thermal expansion of the constituent material of the through-hole conductor 70A (for example, copper). In this case, the resin-filled portion 90A, more specifically, the resin material placed in the through hole 71A, expands under high temperature environment, and the through-hole conductor 70A is pressed from the inside toward the outside of the through hole 71A against the inner wall surface of the through hole 71A. This sufficiently reduces the occurrence of delamination of the through-hole conductor 70A.

However, the coefficient of thermal expansion of the resin-filled portion 90A may be the same as or lower than the coefficient of thermal expansion of the through-hole conductor 70A. More specifically, the coefficient of thermal expansion of the resin material placed in the through hole 71A may be the same as or lower than the coefficient of thermal expansion of the constituent material of the through-hole conductor 70A.

However, the capacitor array 1 may have a configuration without the resin-filled portions 90A. In this case, it is preferable that the through-hole conductor 70A be located not only on the inner wall surface of the through hole 71A but also throughout the entire inside of the through hole 71A.

The capacitor array 1 preferably further includes through-hole conductors 70B.

The through-hole conductors 70B pass through the capacitor portions 10 and the sealing portion 60, more precisely, the sealing portion 60, in the thickness direction T. In the example illustrated in FIG. 2 and other figures, the through-hole conductors 70B pass through the third insulation portions 63 of the first sealing layer 60A and the second sealing layers 60B.

The through-hole conductor 70B is preferably located at least on the inner wall surface of a through hole 71B extending through the capacitor portion 10 and the sealing portion 60, more precisely, the sealing portion 60, in the thickness direction T. In the example illustrated in FIG. 2 and other figures, the through-hole conductor 70B is located not throughout the entire inside of the through hole 71B but on the inner wall surface of the through hole 71B.

The through-hole conductor 70B is formed, for example, as follows: First, a through hole is formed so as to extend through the capacitor portion 10 in the thickness direction T by drilling, laser processing, or the like. Next, the first sealing layer 60A is formed to enclose the capacitor portion 10 so as to cover both main surfaces of the capacitor portion 10, so that the third insulation portion 63 which is a filling of the insulating material in the foregoing through hole is formed. Then, the second sealing layers 60B are formed so as to adjoin the opposite sides of the first sealing layer 60A from the capacitor portion 10. Next, the through hole 71B is formed in the third insulation portion 63 of the first sealing layer 60A and the second sealing layers 60B by drilling, laser processing, or the like. In this process, the diameter of the through hole 71B is set to be smaller than the diameter of the third insulation portion 63, so that the third insulation portion 63 remains between the inner wall surface of the previously formed through hole and the inner wall surface of the through hole 71B in the plane directions. After that, the inner wall surface of the through hole 71B is metallized with a metal material containing a low resistance metal such as copper, gold, and silver to form the through-hole conductor 70B. When forming the through-hole conductor 70B, for example, metallizing the inner wall surface of the through hole 71B by electroless copper plating, electrolytic copper plating, or the like makes the processing easy. Instead of the method in which the inner wall surface of the through hole 71B is metallized, the method of forming the through-hole conductor 70B may be a method in which the through hole 71B is filled with a metal material, a composite material containing a metal and a resin, or the like.

In the case in which the through-hole conductor 70B is located so as to pass through the third insulation portion 63 of the first sealing layer 60A in the thickness direction T as described above, the third insulation portion 63 is located between the capacitor portion 10 and the through-hole conductor 70B, in other words, between the anode plate 20 and the through-hole conductor 70B, in the plane directions. In the example illustrated in FIG. 2 and other figures, the third insulation portion 63 is in contact with both the capacitor portion 10 and the through-hole conductor 70B, in other words, both the anode plate 20 and the through-hole conductor 70B.

Since the third insulation portion 63 of the first sealing layer 60A is located between the capacitor portion 10 and the through-hole conductor 70B, in other words, between the anode plate 20 and the through-hole conductor 70B, in the plane directions, the insulation between the anode plate 20 and the through-hole conductor 70B, in other words, the insulation between the anode plate 20 and the cathode layers 40, is sufficiently achieved, which prevents a short circuit between them.

In the case in which the third insulation portion 63 of the first sealing layer 60A is contact with both the capacitor portion 10 and the through-hole conductor 70B, in other words, both the anode plate 20 and the through-hole conductor 70B, it is preferable that the core portion 21 and the porous layers 22 be exposed on the end surface of the anode plate 20 in contact with the third insulation portion 63 as illustrated in FIG. 2 and other figures. In this case, the contact area between the porous layers 22 and the third insulation portion 63 is large, improving the adhesion between them, so that defects such as separation between the porous layers 22 and the third insulation portion 63 are less likely to occur.

In the case in which the core portion 21 and the porous layers 22 are exposed on the end surface of the anode plate 20 in contact with the third insulation portion 63 of the first sealing layer 60A, it is preferable that the mask layer 50 formed so as to extend inside the porous layer 22 by the constituent material of the mask layer 50 infiltrating into the pores of the porous layer 22 be located around the through-hole conductor 70B. In this case, the insulation between the anode plate 20 and the through-hole conductor 70B, in other words, the insulation between the anode plate 20 and the cathode layer 40 is sufficiently achieved, which sufficiently prevents a short circuit between them.

In the case in which the core portion 21 and the porous layers 22 are exposed on the end surface of the anode plate 20 in contact with the third insulation portion 63 of the first sealing layer 60A, it is preferable that the insulating material composing the third insulation portion 63 infiltrate into the pores of the porous layer 22. This improves the mechanical strength of the porous layer 22, reducing the occurrence of delamination resulting from the pores of the porous layer 22.

It is preferable that the coefficient of thermal expansion of the third insulation portion 63 of the first sealing layer 60A be higher than the coefficient of thermal expansion of the through-hole conductor 70B. More specifically, it is preferable that the coefficient of thermal expansion of the insulating material composing the third insulation portion 63 be higher than the coefficient of thermal expansion of the constituent material of the through-hole conductor 70B (for example, copper). In this case, the third insulation portion 63, more specifically, the insulating material composing the third insulation portion 63, expands under high temperature environment, pressing the porous layers 22 and the through-hole conductor 70B. This sufficiently reduces the occurrence of delamination.

However, the coefficient of thermal expansion of the third insulation portion 63 of the first sealing layer 60A may be the same as or lower than the coefficient of thermal expansion of the through-hole conductor 70B. More specifically, the coefficient of thermal expansion of the insulating material composing the third insulation portion 63 may be the same as or lower than the coefficient of thermal expansion of the constituent material of the through-hole conductor 70B.

The capacitor array 1 preferably includes outer electrode layers 80B electrically connected to the through-hole conductors 70B. In the example illustrated in FIG. 2 and other figures, the outer electrode layers 80B are located on the surfaces of the through-hole conductors 70B and function as connection terminals of the capacitor array 1 (the capacitor portions 10).

Examples of the constituent material of the outer electrode layer 80B include a metal material containing a low resistance metal such as silver, gold, and copper. In this case, the outer electrode layer 80B is formed, for example, by plating the surface of the through-hole conductor 70B.

To improve the adhesion between the outer electrode layer 80B and another member, in this case, the adhesion between the outer electrode layer 80B and the through-hole conductor 70B, the constituent material of the outer electrode layer 80B may contain mixed materials of a resin and at least one kind of conductive fillers selected from the group of silver fillers, copper fillers, nickel fillers, and carbon fillers.

It is preferable that the constituent materials of the outer electrode layer 80A and the outer electrode layer 80B be the same at least in terms of kind, but they may be different.

Although each of the capacitor portions 10 is provided with the outer electrode layers 80A electrically connected to the anode plate 20 and the outer electrode layers 80B electrically connected to the cathode layers 40 in the example illustrated in FIG. 1, at least one of the outer electrode layers 80A and 80B may be shared by the plurality of capacitor portions 10.

Although the outer electrode layer 80A and the outer electrode layer 80B are located on each main surface of the sealing portion 60 in the example illustrated in FIG. 2 and other figures, they may be located on only one main surface of the sealing portion 60.

The capacitor array 1 preferably further includes via conductors 73 penetrating into the sealing portion 60 in the thickness direction T and connected to the cathode layers 40 and the outer electrode layers 80B. In the example illustrated in FIG. 2 and other figures, each via conductor 73 passes through the corresponding first insulation portion 61 of the first sealing layer 60A and the corresponding second sealing layer 60B in the thickness direction T and is connected to the corresponding cathode layer 40 and outer electrode layer 80B.

Examples of the constituent material of the via conductor 73 include a metal material containing a low resistance metal such as silver, gold, and copper.

The via conductor 73 is formed, for example, by plating the inner wall surface of a through hole, which extends through the first insulation portion 61 of the first sealing layer 60A and the second sealing layer 60B in the thickness direction T, with a foregoing metal material or by filling the through hole with a conductive paste and then performing a heat treatment.

When the via conductor 73 is formed by a foregoing method, stress is concentrated at the position on the side surface of the via conductor 73 facing the outer electrode layer 80B, and a crack can occur in the via conductor 73. To address this, in the case in which the insulating material composing the second sealing layer 60B contains a glass cloth as mentioned before, the occurrence of a crack in the via conductor 73 can be reduced as described below.

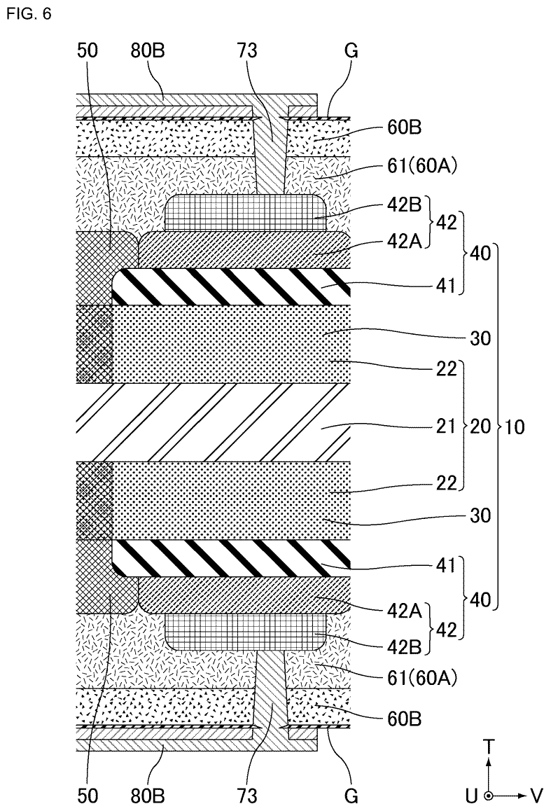

FIG. 6 is an enlarged schematic cross-sectional view of a via conductor and its periphery in a capacitor array for the case the insulating material composing the second sealing layer contains a glass cloth.

In the case in which the insulating material composing the second sealing layer 60B contains a glass cloth, the glass cloth G tends to protrude inward in the plane directions from the inner wall surface of a portion of the through hole in which the via conductor 73 is to be formed, the portion facing the second sealing layer 60B, as illustrated in FIG. 6. When a via conductor 73 is formed by a foregoing method in the through hole into which the glass cloth G protrudes, the protrusion of the glass cloth G distributes the stress, which reduces the occurrence of a crack in the via conductor 73.

In the example illustrated in FIG. 2 and other figures, the through-hole conductor 70B is electrically connected to the cathode layers 40 with the outer electrode layers 80B and the via conductors 73 interposed therebetween. As described above, it is preferable that the through-hole conductor 70B be electrically connected to the cathode layers 40.

In the example illustrated in FIG. 2 and other figures, the outer electrode layers 80B are electrically connected to the cathode layers 40 with the via conductors 73 interposed therebetween and function as the connection terminals for the cathode layers 40.

The capacitor array 1 preferably further includes resin-filled portions 90B formed by filling the through holes 71B with a resin material. In the example illustrated in FIG. 2 and other figures, the resin-filled portion 90B is located in the space surrounded by the through-hole conductor 70B on the inner wall surface of the through hole 71B. Since the presence of the resin-filled portion 90B eliminates the space in the through hole 71B, it reduces the occurrence of delamination of the through-hole conductor 70B.

It is preferable that the coefficient of thermal expansion of the resin-filled portion 90B be higher than the coefficient of thermal expansion of the through-hole conductor 70B. More specifically, it is preferable that the coefficient of thermal expansion of the resin material placed in the through hole 71B be higher than the coefficient of thermal expansion of the constituent material of the through-hole conductor 70B (for example, copper). In this case, the resin-filled portion 90B, more specifically, the resin material placed in the through hole 71B, expands under high temperature environment, and the through-hole conductor 70B is pressed from the inside toward the outside of the through hole 71B against the inner wall surface of the through hole 71B. This sufficiently reduces the occurrence of delamination of the through-hole conductor 70B.

However, the coefficient of thermal expansion of the resin-filled portion 90B may be the same as or lower than the coefficient of thermal expansion of the through-hole conductor 70B. More specifically, the coefficient of thermal expansion of the resin material placed in the through hole 71B may be the same as or lower than the coefficient of thermal expansion of the constituent material of the through-hole conductor 70B.

Note that the capacitor array 1 may have a configuration without the resin-filled portions 90B. In this case, it is preferable that the through-hole conductor 70B be located not only on the inner wall surface of the through hole 71B but also throughout the entire inside of the through hole 71B.

In the capacitor array of the present disclosure, the capacitor portions are not limited to electrolytic capacitors including solid electrolytic capacitors mentioned above. In the capacitor array of the present disclosure, the capacitor portions may be, for example, ceramic capacitors containing barium titanate; thin film capacitors containing silicon nitride (SiN), silicon dioxide (SiO₂), hydrogen fluoride (HF), or the like; trench capacitors having a metal-insulator-metal (MIM) structure; or the like.

In the capacitor array of the present disclosure, to make the capacitor portions thinner and larger in area and to improve the mechanical properties of the capacitor portions such as rigidity and flexibility, it is preferable that the capacitor portions be capacitors containing a metal such as aluminum as a base material, and it is more preferable that the capacitor portions be electrolytic capacitors containing a metal such as aluminum as a base material.

The capacitor array of the present disclosure is used, for example, in a composite electronic component. Such a composite electronic component includes, for example, a capacitor array of the present disclosure and an electronic component electrically connected to outer electrode layers of the capacitor array of the present disclosure.

In the composite electronic component, the electronic component electrically connected to outer electrode layers may be a passive element, an active element, both passive and active elements, or a composite of passive and active elements.

Examples of the passive element include an inductor.

Examples of the active element include a memory, a graphical processing unit (GPU), a central processing unit (CPU), a micro processing unit (MPU), and a power management IC (PMIC).

When the capacitor array of the present disclosure is used in a composite electronic component, the capacitor array of the present disclosure is used, for example, as a substrate for mounting an electronic component. Hence, the capacitor array of the present disclosure is formed in the form of a sheet as a whole, and an electronic component to be mounted on the capacitor array of the present disclosure is formed in the form of a sheet, so that the capacitor array of the present disclosure and the electronic component can be electrically connected in the thickness direction with through-hole conductors passing through the electronic component in the thickness direction interposed therebetween. This makes it possible to form a module including a passive element and an active element, which are electronic components, all together.

For example, a switching regulator can be formed by electrically connecting a capacitor array of the present disclosure between a voltage regulator including a semiconductor active device and a load to which a direct current voltage generated by conversion is supplied.

In a composite electronic component, a circuit layer may be formed on one main surface of a capacitor matrix sheet in which a plurality of capacitor arrays of the present disclosure are laid out, and the circuit layer may be electrically connected to a passive element or an active element which are electronic components.

Alternatively, a capacitor array of the present disclosure is placed in a cavity portion formed in advance in a substrate, and a resin is placed in the cavity. Then, a circuit layer may be formed on the resin. A passive element or an active element, which is another electronic component, may be mounted in another cavity portion in the same substrate.

Alternatively, a capacitor array of the present disclosure is mounted on a smooth carrier such as a wafer or a glass. An outer layer portion is formed by using a resin, and then a circuit layer is formed. The circuit layer may be electrically connected to a passive element or an active element which is an electronic component.

The present specification discloses the following.
<1> A capacitor array including: a plurality of capacitor portions arranged in a plane direction or plane directions orthogonal to a thickness direction; and a sealing portion enclosing the plurality of capacitor portions so as to cover opposed main surfaces of the plurality of capacitor portions, wherein the sealing portion includes a plurality of sealing layers laminated in the thickness direction, and the plurality of sealing layers include: a first sealing layer proximal to the capacitor portions in the thickness direction, and containing a first insulating material; and second sealing layers on opposite respective sides of the first sealing layer relative to the capacitor portions in the thickness direction and forming two main surfaces of the sealing portion opposed to each other in the thickness direction, and containing a second insulating material.
<2> The capacitor array according to <1>, in which each of the capacitor portions includes an anode plate including a porous layer on at least one main surface of two main surfaces of the anode plate opposed to each other in the thickness direction, a dielectric layer on a surface of the porous layer, and a cathode layer on a surface of the dielectric layer.
<3>The capacitor array according to <1> or <2>, in which the first insulating material contains an insulating resin.
<4> The capacitor array according to <3>, in which

the first insulating material further contains inorganic fillers.
<5> The capacitor array according to <4>, in which a median diameter D₅₀ of the inorganic fillers in the first insulating material is 10 μm or less.
<6> The capacitor array according to any one of <1> to <5>, in which the second insulating material contains an insulating resin.
<7> The capacitor array according to <6>, in which

the first insulating material and the second insulating material contain different insulating resins.
<8> The capacitor array according to <6> or <7>, in which the second insulating material further contains inorganic fillers.
<9> The capacitor array according to any one of <6> to <8>, in which the second insulating material further contains a glass cloth.
<10> The capacitor array according to any one of <1> to <9>, in which a coefficient of linear expansion of the second sealing layers in the thickness direction is lower than a coefficient of linear expansion of the first sealing layer in the thickness direction.
<11> The capacitor array according to any one of <1> to <10>, in which the first sealing layer includes first insulation portions each covering a corresponding one of the two main surfaces of the plurality of capacitor portions.
<12> The capacitor array according to <11>, in which in a region of the sealing portion on one main surface side of the two main surfaces of the sealing portion, a maximum dimension of a corresponding one of the first insulation portions of the first sealing layer in the thickness direction and a maximum dimension of a corresponding one of the second sealing layers in the thickness direction differ from each other.
<13> The capacitor array according to <12>, in which in the region of the sealing portion on the one main surface side of the two main surfaces of the sealing portion, the maximum dimension of the corresponding one of the first insulation portions of the first sealing layer in the thickness direction is larger than the maximum dimension of the corresponding one of the second sealing layers in the thickness direction.
<14> The capacitor array according to <13>, in which in the region of the sealing portion on the one main surface side of the two main surfaces of the sealing portion, a ratio of the maximum dimension of the corresponding one of the first insulation portions of the first sealing layer in the thickness direction to the maximum dimension of the corresponding one of the second sealing layers in the thickness direction is 110% or more.
<15> The capacitor array according to <13> or <14>, in which in the region of the sealing portion on the one main surface side of the two main surfaces of the sealing portion, the maximum dimension of the corresponding one of the first insulation portions of the first sealing layer in the thickness direction is 5 μm or more.
<16> The capacitor array according to any one of <13> to <15>, in which in the region of the sealing portion on the one main surface side of the two main surfaces of the sealing portion, the maximum dimension of the corresponding one of the second sealing layers in the thickness direction is 100 μm or less.
<17> The capacitor array according to any one of <13> to <16>, in which in the region of the sealing portion on the one main surface side of the two main surfaces of the sealing portion, a ratio of a minimum dimension of the corresponding one of the first insulation portions of the first sealing layer in the thickness direction to the maximum dimension of the corresponding one of the first insulation portions of the first sealing layer in the thickness direction is 50% or less.
<18> The capacitor array according to any one of <11> to <17>, in which the first sealing layer further includes a second insulation portion separating each of the plurality of capacitor portions from each other.
<19> The capacitor array according to any one of <11> to <18>, in which the first sealing layer further includes third insulation portions each passing through the corresponding one of the plurality of capacitor portions in the thickness direction.
<20> The capacitor array according to any one of <1> to <19>, further including through-hole conductors each respectively passing through the corresponding one of the capacitor portions and the sealing portion in the thickness direction.

### Reference Signs List

1 CAPACITOR ARRAY
10 CAPACITOR PORTION
20 ANODE PLATE
21 CORE PORTION
22 POROUS LAYER
30 DIELECTRIC LAYER
40 CATHODE LAYER
41 SOLID ELECTROLYTE LAYER
42 CONDUCTOR LAYER
42A CONDUCTIVE RESIN LAYER
42B METAL LAYER
50 MASK LAYER
60 SEALING PORTION
60A FIRST SEALING LAYER
60B SECOND SEALING LAYER
61 FIRST INSULATION PORTION
62 SECOND INSULATION PORTION
63 THIRD INSULATION PORTION
70A, 70B THROUGH-HOLE CONDUCTOR
71A, 71B THROUGH HOLE
72 ANODE CONNECTION LAYER
73 VIA CONDUCTOR
80A, 80B OUTER ELECTRODE LAYER
90A, 90B RESIN-FILLED PORTION
da1 MAXIMUM DIMENSION OF FIRST INSULATION PORTION OF FIRST SEALING LAYER IN THICKNESS DIRECTION
da2 MINIMUM DIMENSION OF FIRST INSULATION PORTION OF FIRST SEALING LAYER IN THICKNESS DIRECTION
db1 MAXIMUM DIMENSION of SECOND SEALING LAYER IN THICKNESS DIRECTION
G GLASS CLOTH
T THICKNESS DIRECTION
U FIRST DIRECTION
V SECOND DIRECTION

1. A capacitor array comprising:
a plurality of capacitor portions arranged in a plane direction or plane directions orthogonal to a thickness direction; and
a sealing portion enclosing the plurality of capacitor portions so as to cover opposed main surfaces of the plurality of capacitor portions, wherein the sealing portion includes a plurality of sealing layers laminated in the thickness direction, and the plurality of sealing layers include:
a first sealing layer proximal to the capacitor portions in the thickness direction, and containing a first insulating material; and
second sealing layers on opposite respective sides of the first sealing layer relative to the capacitor portions in the thickness direction and forming two main surfaces of the sealing portion opposed to each other in the thickness direction, and containing a second insulating material.

2. The capacitor array according to claim 1, wherein each of the capacitor portions include:
an anode plate including a porous layer on at least one main surface of two main surfaces of the anode plate opposed to each other in the thickness direction;
a dielectric layer on a surface of the porous layer; and
a cathode layer on a surface of the dielectric layer.

3. The capacitor array according to claim 1, wherein the first insulating material contains an insulating resin.

4. The capacitor array according to claim 3, wherein the first insulating material further contains inorganic fillers.

5. The capacitor array according to claim 4, wherein a median diameter D₅₀ of the inorganic fillers in the first insulating material is 10 μm or less.

6. The capacitor array according to claim 1, wherein the second insulating material contains an insulating resin.

7. The capacitor array according to claim 1, wherein the first insulating material and the second insulating material contain different insulating resins.

8. The capacitor array according to claim 6, wherein the second insulating material further contains inorganic fillers.

9. The capacitor array according to claim 6, wherein the second insulating material further contains a glass cloth.

10. The capacitor array according to claim 1, wherein a coefficient of linear expansion of the second sealing layers in the thickness direction is lower than a coefficient of linear expansion of the first sealing layer in the thickness direction.

11. The capacitor array according to claim 1, wherein the first sealing layer includes first insulation portions each covering a corresponding one of the two main surfaces of the plurality of capacitor portions.

12. The capacitor array according to claim 11, wherein in a region of the sealing portion on one main surface side of the two main surfaces of the sealing portion, a maximum dimension of a corresponding one of the first insulation portions of the first sealing layer in the thickness direction and a maximum dimension of a corresponding one of the second sealing layers in the thickness direction differ from each other.

13. The capacitor array according to claim 12, wherein in the region of the sealing portion on the one main surface side of the two main surfaces of the sealing portion, the maximum dimension of the corresponding one of the first insulation portions of the first sealing layer in the thickness direction is larger than the maximum dimension of the corresponding one of the second sealing layers in the thickness direction.

14. The capacitor array according to claim 13, wherein in the region of the sealing portion on the one main surface side of the two main surfaces of the sealing portion, a ratio of the maximum dimension of the corresponding one of the first insulation portions of the first sealing layer in the thickness direction to the maximum dimension of the corresponding one of the second sealing layers in the thickness direction is 110% or more.

15. The capacitor array according to claim 13, wherein in the region of the sealing portion on the one main surface side of the two main surfaces of the sealing portion, the maximum dimension of the corresponding one of the first insulation portions of the first sealing layer in the thickness direction is 5 μm or more.

16. The capacitor array according to claim 13, wherein in the region of the sealing portion on the one main surface side of the two main surfaces of the sealing portion, the maximum dimension of the corresponding one of the second sealing layers in the thickness direction is 100 μm or less.

17. The capacitor array according to claim 13, wherein in the region of the sealing portion on the one main surface side of the two main surfaces of the sealing portion, a ratio of a minimum dimension of the corresponding one of the first insulation portions of the first sealing layer in the thickness direction to the maximum dimension of the corresponding one of the first insulation portions of the first sealing layer in the thickness direction is 50% or less.

18. The capacitor array according to claim 11, wherein the first sealing layer further includes a second insulation portion separating each of the plurality of capacitor portions from each other.

19. The capacitor array according to claim 11, wherein the first sealing layer further includes third insulation portions each passing through the corresponding one of the plurality of capacitor portions in the thickness direction.

20. The capacitor array according to claim 1, further comprising through-hole conductors each respectively passing through the corresponding one of the capacitor portions and the sealing portion in the thickness direction.
